(19) United States
(12) Patent Application Publication
(10) Pub. No.: US 2025/0234713 A1
(43) Pub. Date: Jul. 17, 2025

(54) DISPLAY DEVICE

(71) Applicant: Samsung Display Co., Ltd., Yongin-si (KR)

(72) Inventors: Dong Hee SHIN, Yongin-si (KR); Sun Kwun SON, Yongin-si (KR); Sang Yong NO, Yongin-si (KR); Na Hyeon CHA, Yongin-si (KR)

(73) Assignee: Samsung Display Co., Ltd., Yongin-si (KR)

(21) Appl. No.: 18/804,652

(22) Filed: Aug. 14, 2024

(30) Foreign Application Priority Data
Jan. 16, 2024 (KR) 10-2024-0006484

(51) Int. Cl. H10K 59/122; H10K 59/131; H10K 59/88

(52) U.S. Cl. CPC H10K 59/122; H10K 59/131; H10K 59/88

(57) ABSTRACT

A display device includes a substrate; a pixel electrode, a pixel defining layer, a light emitting layer, a common electrode, and a first dummy layer. The pixel electrode is disposed on a surface of the substrate. The pixel defining layer is disposed on the pixel electrode. The pixel defining layer at least partially bounds an emission area overlapping the pixel electrode in a direction perpendicular to the surface. The light emitting layer is disposed on the pixel electrode. The common electrode is disposed on the light emitting layer. The first dummy layer overlaps the pixel electrode in the emission area in the direction.

### CROSS-REFERENCE TO RELATED APPLICATION(S)

This U.S. non-provisional patent application claims priority to and the benefits of Korean Patent Application No. 10-2024-0006484 under 35 U.S.C. § 119, filed in the Korean Intellectual Property Office on Jan. 16, 2024, the entire contents of which are hereby incorporated by reference.

### BACKGROUND

### 1. Technical Field

The disclosure generally relates to a display device capable of improving image quality by minimizing (or at least reducing) color differences depending on a viewing angle.

### 2. Description of the Related Art

Organic light emitting diode displays have self-luminous properties, and unlike liquid crystal displays, do not require a separate light source, thus reducing thickness and weight. In addition, organic light emitting diode displays are drawing attention as next-generation displays for TVs, monitors, portable electronic devices, and the like due to their relatively high-quality characteristics, such as relatively low power consumption, relatively high luminance, and relatively high response speed.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

Some aspects provide a display device capable of improving image quality by minimizing (or at least reducing) color differences depending on a viewing angle.

Additional aspects will be set forth in the detailed description, which follows, and in part, will be apparent from the disclosure, or may be learned by practice of the disclosed embodiments and/or the claimed subject matter.

According to some embodiments, a display device includes a substrate; a pixel electrode, a pixel defining layer, a light emitting layer, a common electrode, and a first dummy layer. The pixel electrode is disposed on a surface of the substrate. The pixel defining layer is disposed on the pixel electrode. The pixel defining layer at least partially bounds an emission area overlapping the pixel electrode in a direction perpendicular to the surface. The light emitting layer is disposed on the pixel electrode. The common electrode is disposed on the light emitting layer. The first dummy layer overlaps the pixel electrode in the emission area in the direction.

In an embodiment, the pixel electrode may include a first stepped portion in an area overlapping the first dummy layer in the direction.

In an embodiment, the pixel electrode may overlap the first dummy layer in the direction at an edge of the emission area.

In an embodiment, the first dummy layer may be disposed between the substrate and the pixel electrode in the direction.

In an embodiment, the first dummy layer may include a first opening overlapping the emission area in the direction.

In an embodiment, in a view in the direction, an outer boundary of the emission area may circumscribe the first opening.

In an embodiment, a first portion of the first dummy layer may overlap the emission area in the direction, a second portion of the first dummy layer may overlap the pixel defining layer in the direction, and the first portion may be closer to the first opening than the second portion.

In an embodiment, an outer boundary of the first dummy layer may, in a view in the direction, circumscribe an inner boundary of the first dummy layer defining the first opening.

In an embodiment, the display device may further include a static power supply line electrically connected to the first dummy layer.

In an embodiment, the first dummy layer may include a metal material.

In an embodiment, the display device may further include an insulating layer between the first dummy layer and the pixel electrode in the direction.

In an embodiment, the insulating layer may have a first stepped portion in an area in which the pixel electrode and the dummy layer overlap each other in the direction.

In an embodiment, the display device may further include a second dummy layer disposed on the first dummy layer.

In an embodiment, the pixel electrode may include a first stepped portion in an area overlapping the first dummy layer in the direction, and a second stepped portion in an area overlapping the second dummy layer in the direction.

In an embodiment, the pixel electrode may overlap both the first dummy layer and the second dummy layer in the direction at an edge of the emission area.

In an embodiment, the first dummy layer may be disposed between the substrate and the pixel electrode in the direction, and the second dummy layer may be disposed between the first dummy layer and the pixel electrode in the direction.

In an embodiment, the first dummy layer may have a first opening overlapping the emission area in the direction, and the second dummy layer may have a second opening overlapping the emission area in the direction.

In an embodiment, in a view in the direction, an outer boundary of the second opening may circumscribe an outer boundary of the first opening, and an outer boundary of the emission area may circumscribe an outer boundary of the second opening.

In an embodiment, a cross-sectional area of the second opening of the second dummy layer in a first plane perpendicular to the direction may be larger than a cross-sectional area of the first opening of the first dummy layer in a second plane perpendicular to the direction. The cross-sectional area of the second opening of the second dummy layer in the first plane may be smaller than a cross-sectional area of the emission area in a third plane perpendicular to the direction. The first plane, the second plane, and the third plane may be parallel with one another.

In an embodiment, in a view in the direction, an inner surface of the second dummy layer may be disposed between an inner surface of the pixel defining layer and an inner surface of the first dummy layer.

In an embodiment, in the emission area, an amount of overlapping area between the first dummy layer and the pixel electrode in the direction may be greater than an amount of overlapping area between the second dummy layer and the pixel electrode in the direction.

According to some embodiments, display device includes a substrate, a first pixel electrode, a second pixel electrode, a first emission area, a second emission area, a first light emitting layer, a second light emitting layer, a common electrode, a first dummy layer, a second dummy layer, and a third dummy layer. The first pixel electrode is disposed on a surface of the substrate. The second pixel electrode is disposed on the surface. The first emission area overlaps the first pixel electrode in a direction perpendicular to the surface. The second emission area overlaps the second pixel electrode in the direction. The first light emitting layer is disposed on the first pixel electrode. The second light emitting layer is disposed on the second pixel electrode. The common electrode is disposed on both the first light emitting layer and the second light emitting layer. The first dummy layer overlaps, in the first emission area, the first pixel electrode in the direction. The second dummy layer overlaps, in the second emission area, the second pixel electrode in the direction. The third dummy layer is disposed on the second dummy layer and overlaps, in the second emission area, the second pixel electrode in the direction.

In an embodiment, the first pixel electrode may be part of a first pixel group, and the second pixel electrode may be part of a second pixel group different from the first pixel group.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 is a perspective view schematically showing a display device according to an embodiment.

FIG. 2 is a cross-sectional view schematically illustrating a display device according to an embodiment.

FIG. 3 is a plan view schematically illustrating a display panel of a display device according to an embodiment.

FIG. 4 is a block diagram schematically illustrating a display panel and a display driver according to an embodiment.

FIG. 5 is a plan view schematically illustrating a display device according to an embodiment.

FIG. 6 is an enlarged view schematically illustrating a pixel according to an embodiment.

FIG. 7 schematically illustrates a cross-sectional view of a pixel taken along sectional line I-I′ in FIG. 6 according to an embodiment.

FIG. 8 is an enlarged view schematically illustrating a pixel according to an embodiment.

FIG. 9 schematically illustrates a cross-sectional view of a pixel taken along sectional line II-II′ in FIG. 8 according to an embodiment.

FIG. 10 is an enlarged view schematically illustrating a pixel according to an embodiment.

FIG. 11 schematically illustrates a cross-sectional view of a pixel taken along sectional line III-III′ in FIG. 10 according to an embodiment.

FIG. 12 is a perspective view schematically illustrating a display device according to an embodiment.

FIG. 13 is a perspective view schematically illustrating a display device in an expanded state according to an embodiment.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, well-known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. When an embodiment may be implemented differently, a specific process order may be performed differently from the described order. For example, two consecutively described processes may be performed substantially at the same time or performed in an order opposite the described order. Also, like reference numerals and/or reference characters denote like elements.

When an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. When, however, an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items—it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the term “substantially,” if used herein, and unless otherwise specified, may mean within 5% of a referenced value. For example, substantially perpendicular may mean within ±5% of being parallel. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the particular illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, various embodiments will be described with reference to the accompanying drawings.

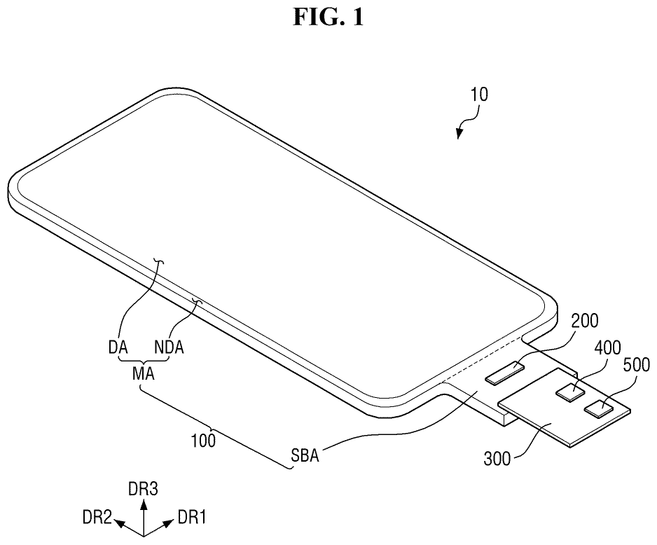

FIG. 1 is a perspective view schematically showing a display device according to an embodiment.

Referring to FIG. 1, a display device 10 may be applied to (or used in association with) a portable electronic device, such as a mobile phone, a smartphone, a tablet personal computer (PC), a mobile communication terminal, an electronic organizer, an electronic book, a portable multimedia player (PMP), a navigation system, an ultra mobile PC (UMPC), or the like. In some implementations, the display device 10 may be applied as a display of a television, a laptop, a monitor, a billboard, or an Internet-of-Things (IoT) device. It is also contemplated that the display device 10 may be applied to a wearable device, such as a smart watch, a watch phone, a glasses type display, or a head mounted display (HMD). Embodiments, however, are not limited to the above-noted applications.

The display device 10 may have a planar shape, such as or similar to a quadrilateral shape. For example, the display device 10 may have a planar shape similar to a quadrilateral shape having a short side in the first direction DR1 and a long side in the second direction DR2, which may be transverse to the first direction DR1. A corner where the short side in the first direction DR1 and the long side in the second direction DR2 meet may be right-angled or rounded with a determined curvature. The planar shape of the display device 10 is not limited to a quadrilateral shape, and may be formed in (or as) a shape such as or similar to another polygonal shape, a circular shape, an elliptical shape, an oval shape, etc.

The display device 10 may include a display panel 100, a display driver 200, a circuit board 300, a touch driver 400, and a power supply 500.

The display panel 100 may include a main region MA and a sub-region SBA.

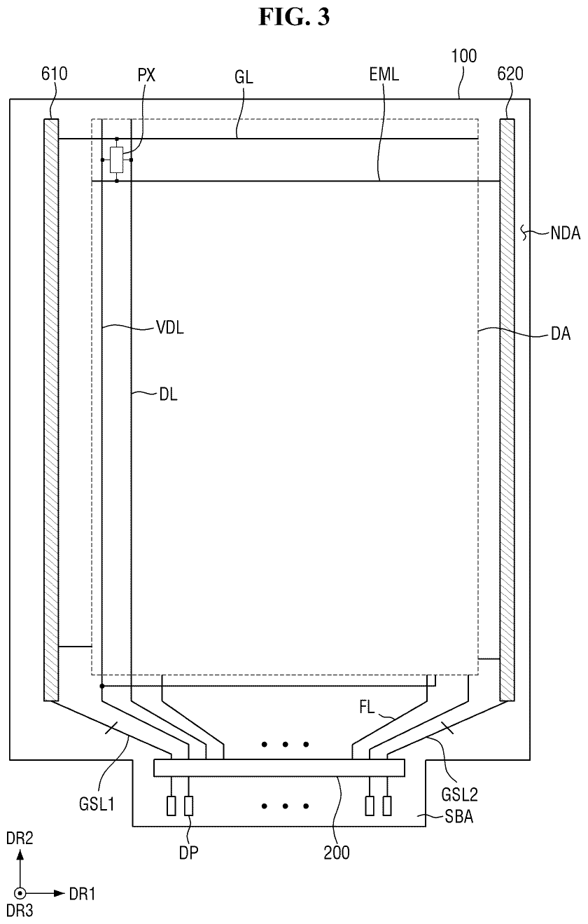

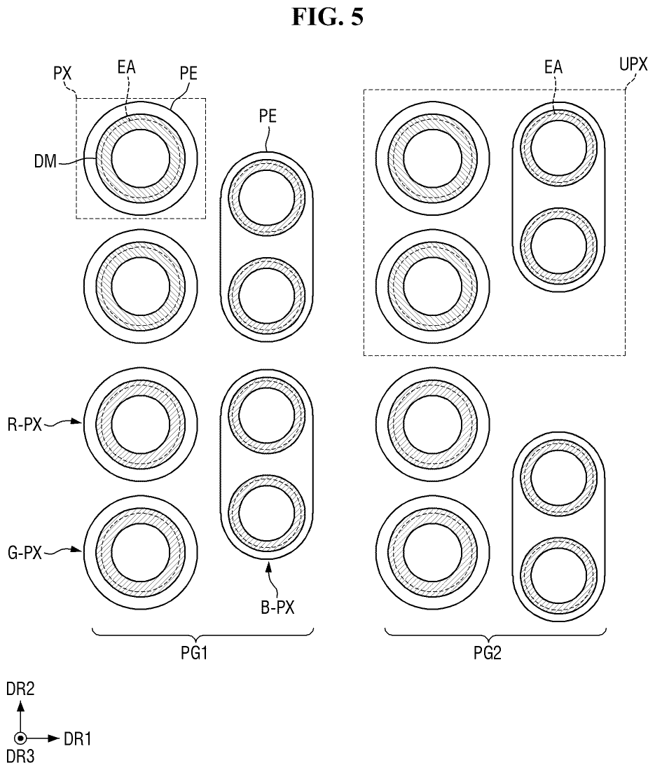

The main region MA may include a display area DA including pixels PX (see FIG. 3) configured to display an image and a non-display area NDA disposed outside, e.g., around, adjacent to, etc., the display area DA. The display area DA may emit light from multiple emission areas EA (see, e.g., FIG. 5) or multiple opening areas. For example, the display panel 100 may include a pixel circuit including one or more switching elements, a pixel defining layer defining an emission area EA or an opening area, and a light emitting element ED, which may be self-luminous.

For example, the light emitting element ED may include at least one of an organic light emitting diode (LED) including an organic light emitting layer, a quantum dot LED including a quantum dot light emitting layer, an inorganic LED including an inorganic semiconductor, a micro-LED, and a nano-LED, but embodiments are not limited to the aforementioned examples of light emitting elements ED.

The non-display area NDA may be an area outside the display area DA. The non-display area NDA may be defined as an edge (or peripheral) area of the main region MA of the display panel 100. The non-display area NDA may include a gate driver (e.g., gate driver 610 shown in FIG. 3) configured to supply gate signals to gate lines GL (see FIG. 3), and fan-out lines FL (see FIG. 3) that connect a display driver 200 (see FIG. 3) to the display area DA.

The sub-region SBA may extend from one (or a) side of the main region MA. The sub-region SBA may include a flexible material, which may be configured to be elastically (or at least intentionally) bent, folded, rolled, twisted, and/or otherwise flexed. For example, in a case that the sub-region SBA is bent, the sub-region SBA may overlap the main region MA in a thickness direction (e.g., in the third direction DR3, which may be transverse to both the first direction DR1 and the second direction DR2). The sub-region SBA may include the display driver 200 and a pad portion (e.g., pad portion PD in FIG. 3) electrically connected to the circuit board 300. Optionally, the sub-region SBA may be omitted, and the display driver 200 and the pad portion PD may be arranged in (or on) the non-display area NDA.

The display driver 200 may be configured to output signals and voltages for driving the display panel 100. The display driver 200 may supply data voltages to data lines DL (see FIG. 3). The display driver 200 may supply a power voltage to a power line (e.g., driving voltage line VDL in FIG. 3) and may supply a gate control signal to the gate driver (e.g., gate driver 610 in FIG. 3). The display driver 200 may be formed as an integrated circuit (IC) and mounted on the display panel 100 using at least one of a chip on glass (COG) mounting method, a chip on plastic (COP) mounting method, and an ultrasonic bonding method. For example, the display driver 200 may be disposed in the sub-region SBA and may overlap the main region MA in the thickness direction (e.g., the third direction DR3) by bending the sub-region SBA about a bending axis extending in, for instance, the first direction DR1. In some implementations, the display driver 200 may be mounted on the circuit board 300.

The circuit board 300 may be physically attached to the pad portion PD of the display panel 100 using an anisotropic conductive film (ACF), but any other suitable technique may be utilized, such as soldering. Lead lines of the circuit board 300 may be electrically connected to the pad portion PD of the display panel 100. The circuit board 300 may be at least one of a flexible printed circuit board, a printed circuit board, and a flexible film, such as a chip on film.

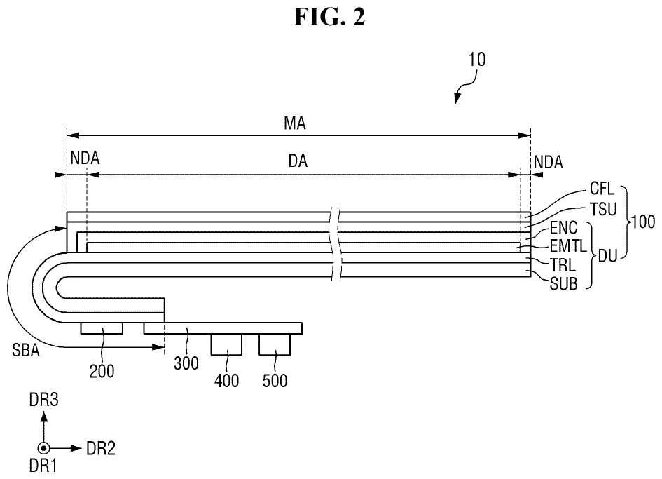

The touch driver 400 may be mounted on the circuit board 300. The touch driver 400 may be electrically connected to a touch sensing layer (e.g., touch sensing layer TSU in FIG. 2) of (or disposed on) the display panel 100. The touch driver 400 may supply a touch driving signal to multiple touch electrodes of, for example, the touch sensing layer TSU and may sense an amount of change in, for instance, capacitance between the multiple touch electrodes. For example, the touch driving signal may be a pulse signal having a determined frequency. The touch driver 400 may calculate (or determine) whether an input is made and input coordinates of the input based on an amount of change in capacitance between the multiple touch electrodes. It is contemplated, however, that the touch driver 400 and the touch sensing layer TSU may be configured to detect touch inputs using any other (or additional) technique, such as inductively, magnetically, optically, ultrasonically, etc. The touch driver 400 may be formed of (or as) an integrated circuit (IC).

The power supply 500 may be disposed on the circuit board 300 and may be configured to supply a power voltage to at least one of the display driver 200 and the display panel 100. The power supply 500 may generate a driving voltage and supply the generated driving voltage to a driving voltage line VDL (see FIG. 3), generate an initialization voltage (e.g., a first initialization voltage and a second initialization voltage) and supply the initialization voltage to an initialization voltage line (e.g., a first initialization voltage line and a second initialization voltage line), and generate a common voltage and supply the common voltage to a common electrode, which may be formed in common with multiple light emitting elements ED of one or more pixels PX. For example, the power supply 500 may supply the common voltage to a common voltage line connected to the common electrode. In an embodiment, the driving voltage may be a relatively high potential voltage for driving a light emitting element ED, and the common voltage may be a relatively low potential voltage for driving the light emitting element ED. In some implementations, the driving voltage may exhibit a first voltage level and the common voltage may exhibit a second voltage level different from the first voltage level.

FIG. 2 is a cross-sectional view schematically illustrating a display device according to an embodiment.

Referring to FIG. 2, the display panel 100 may include a display layer DU, a touch sensing layer TSU, and a color filter layer CFL. The display layer DU may include a substrate SUB, a transistor layer TRL, a light emitting element layer EMTL, and an encapsulation layer ENC.

The substrate SUB may be a base substrate SUB or a base member. The substrate SUB may be a flexible substrate SUB, which may be configured to be elastically (or at least intentionally) bent, folded, rolled, twisted, and/or otherwise flexed. For example, the substrate SUB may include a polymer resin, such as polyimide (PI), but a material of the substrate SUB is not limited to this example. For instance, the substrate SUB may additionally or alternatively include at least one of a glass material and a metal material. In some implementations, the substrate SUB may have a multilayer configuration and at least one of the layers of the substrate SUB may include at least one material that is different from at least one material of at least one other layer of the substrate SUB.

The transistor layer TRL may be disposed on the substrate SUB. The transistor layer TRL may include a plurality of thin film transistors constituting one or more pixel circuits of the pixels PX. The transistor layer TRL may further include gate lines GL, data lines DL, power lines (e.g., driving voltage line VDL in FIG. 3), gate control lines (e.g., first and second gate control lines GSL1 and GSL2 in FIG. 3), fan-out lines FL that electrically connect the display driver 200 to the data lines DL, and lead lines that electrically connect the display driver 200 to the pad portion (e.g., pad portion DP in FIG. 3). Each of the thin film transistors may include a semiconductor region, a source electrode, a drain electrode, and a gate electrode. For example, in a case that the gate driver 610 is formed on one (or a first) side of the non-display area NDA of the display panel 100, the gate driver 610 may include thin film transistors.

The transistor layer TRL may be disposed in the display area DA, the non-display area NDA, and the sub-region SBA. Thin film transistors, gate lines GL, data lines DL, and power lines (e.g., driving voltage line VDL) of each of the pixels PX of the transistor layer TRL may be disposed in the display area DA. Gate control lines (e.g., first and second gate control lines GSL1 and GSL2) and fan-out lines FL of the transistor layer TRL may be disposed in the non-display area NDA. The lead lines of the transistor layer TRL may be disposed in the sub-region SBA.

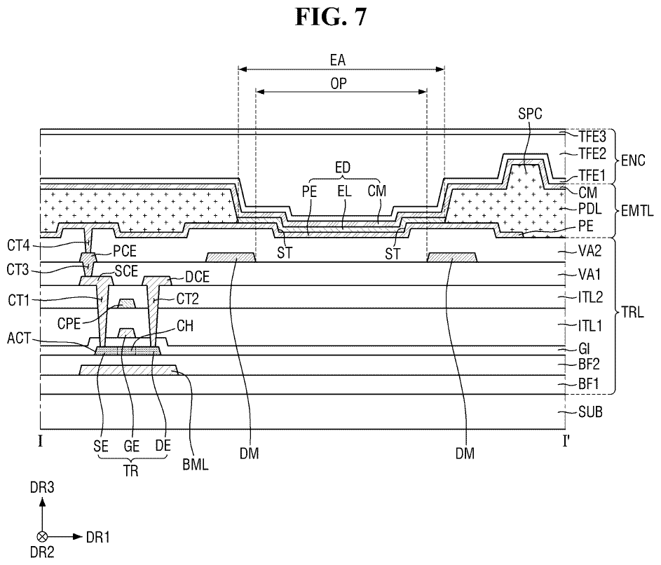

The light emitting element layer EMTL may be disposed on the transistor layer TRL. The light emitting element layer EMTL may include multiple light emitting elements ED, which may include a pixel (or first) electrode PE (see FIG. 7), a light emitting layer EL (see FIG. 7), and a common (or second) electrode CM (see FIG. 7) that are sequentially stacked on each other in, for example, the third direction DR3. The light emitting elements ED may be configured to emit light based on a flow of current between the pixel electrode PE and the common electrode CM. In some implementations, the light emitting elements ED may also include a pixel defining layer (e.g., pixel defining layer PDL in FIG. 7) defining or at least partially bounding the pixels PX. The light emitting elements ED of the light emitting element layer EMTL may be disposed in the display area DA.

According to some embodiments, the light emitting layer EL may be an organic light emitting layer including an organic material. The light emitting layer EL may include a hole transporting layer, an organic light emitting layer, and an electron transporting layer. In a case that the pixel electrode PE receives a determined voltage through a transistor (e.g., a thin film transistor) of the transistor layer TRL and the common electrode CM receives a common voltage, holes and electrons may be transferred to the organic light emitting layer through the hole transporting layer and the electron transporting layer, respectively, and may be combined with each other to emit light in the organic light emitting layer. In some implementations, the pixel electrode PE may be an anode electrode, and the common electrode CM may be a cathode electrode, but embodiments are not limited to this example. For instance, the pixel electrode PE may be a cathode electrode, and the common electrode CM may be anode electrode.

In some embodiments, the light emitting elements ED may include at least one of a quantum dot light emitting diode including a quantum dot light emitting layer, an inorganic light emitting diode including an inorganic semiconductor, a micro light emitting diode, and a nano light emitting diode.

The encapsulation layer ENC may cover the top surface and the side surface of the light emitting element layer EMTL, and may protect the light emitting element layer EMTL from, for instance, debris, moisture, impact, etc. The encapsulation layer ENC may include at least one inorganic layer and at least one organic layer for encapsulating the light emitting element layer EMTL.

The touch sensing layer TSU may be disposed on the encapsulation layer ENC. The touch sensing layer TSU may include multiple touch electrodes for sensing a user's touch in a capacitive manner, and touch lines connecting the multiple touch electrodes to the touch driver 400. For example, the touch sensing layer TSU may sense the user's touch using a mutual capacitance method or a self-capacitance method. However, as previously mentioned, any other or additional sensing technique and associated structure may be utilized in association with touch sensing layer TSU and touch driver 400.

In some implementations, the touch sensing layer TSU may be disposed on at least one other substrate, which may be disposed on the display layer DU. The at least one other substrate supporting the touch sensing layer TSU may be a base member that encapsulates the display layer DU. Any other suitable configuration of the touch sensing layer TSU may be utilized in association with display device 10.

The multiple touch electrodes of the touch sensing layer TSU may be disposed in a touch sensor area (or active area) overlapping the display area DA in, for example, the third direction DR3. The touch lines of the touch sensing layer TSU may be disposed in a touch peripheral area (or inactive area) that overlaps the non-display area NDA in, for example, the third direction DR3.

The color filter layer CFL may be disposed on the touch sensing layer TSU. The color filter layer CFL may include multiple color filters respectively corresponding to the multiple emission areas EA. Each of the color filters may selectively transmit light of a first wavelength (or a range of first wavelengths) and may block or absorb light of a different wavelength (or a range of different wavelengths). The color filter layer CFL may absorb a portion of incident ambient light coming from outside of the display device 10 to reduce an amount of reflected light from display device 10. Accordingly, the color filter layer CFL may prevent (or at least mitigate) color distortion caused, at least in part, by reflection of external light.

According to some embodiments, the color filter layer CFL may be disposed directly on the touch sensing layer TSU, and as such, the display device 10 may not include a separate substrate to support the color filter layer CFL. Therefore, the thickness of the display device 10 may be relatively reduced.

The sub-region SBA of the display panel 100 may extend from one (or a first) side of the main region MA. The sub-region SBA may include a flexible material, which may be configured to be elastically (or at least intentionally) bent, folded, rolled, twisted, and/or otherwise flexed. For example, in a case that the sub-region SBA is bent, the sub-region SBA may overlap the main region MA in a thickness direction (e.g., in the third direction DR3). The sub-region SBA may include the display driver 200 and the pad portion PD electrically connected to the circuit board 300.

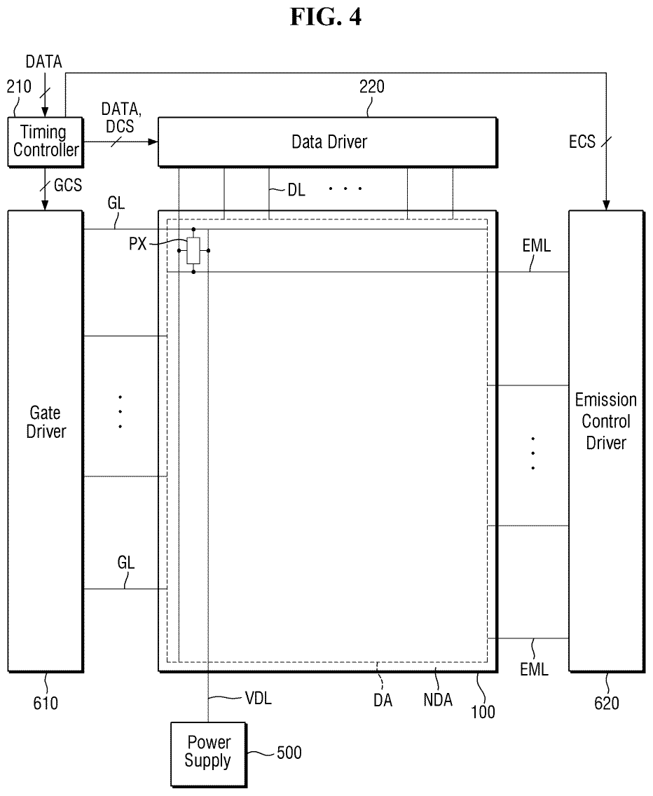

FIG. 3 is a plan view schematically illustrating a display panel of a display device according to an embodiment. FIG. 4 is a block diagram schematically illustrating a display panel and a display driver according to an embodiment.

Referring to FIGS. 3 and 4, the display panel 100 may include the display area DA and the non-display area NDA.

The display area DA may not only include multiple pixels PX, but may also include multiple driving voltage lines VDL, multiple common voltage lines, multiple gate lines GL, multiple emission control lines EML, and multiple data lines DL electrically connected to the pixels PX.

Each of the pixels PX may be electrically connected to at least one gate line GL, at least one data line DL, at least one driving voltage line VDL, and at least one common voltage line. Each of the pixels PX may include at least one transistor, at least one light emitting element ED, and at least one capacitor.

Each of the gate lines GL may extend in the first direction DR1 and may be spaced apart from each other in the second direction DR2, which may be transverse to the first direction DR1. For instance, the gate lines GL may be arranged along the second direction DR2. The gate lines GL may supply (e.g., sequentially supply) gate signals to the pixels PX.

The data lines DL may extend in the second direction DR2 and may be spaced apart from each other in the first direction DR1. For instance, the data lines DL may be arranged along the first direction DR1. The data lines DL may supply data voltages to the pixels PX. The data voltages may respectively determine (or affect) the luminance of each of the pixels PX. According to an embodiment, a pixel PX may be connected to two different data lines among the data lines DL. For example, a pixel PX may be connected to a first data line and a second data line.

The driving voltage lines VDL may extend in the second direction DR2 and may be spaced apart from each other in the first direction DR1. For instance, the driving voltage lines VDL may be arranged along the first direction DR1. The driving voltage lines VDL may supply a driving voltage to the pixels PX. The driving voltage may be a relatively high potential voltage for driving the light emitting elements ED of the pixels PX.

The non-display area NDA may be disposed outside, e.g., surround, the display area DA. The non-display area NDA may include a gate driver 610, fan-out lines FL, and one or more gate control lines, such as first and second gate control lines GSL1 and GSL2.

The fan-out lines FL may extend from the display driver 200 to the display area DA. The fan-out lines FL may supply the data voltage received from, for instance, the display driver 200 to the data lines DL.

The first gate control line GSL1 may extend from the display driver 200 to the gate driver 610. The first gate control line GSL1 may supply a gate control signal GCS received from, for instance, the display driver 200 to the gate driver 610.

The sub-region SBA may extend from one (or a first) side of the non-display area NDA. The sub-region SBA may include the display driver 200 and the pad portion DP. The pad portion DP may be disposed closer to one (or a first) edge of the sub-region SBA than the display driver 200. The pad portion DP may be electrically connected to the circuit board 300 through, for instance, an anisotropic conductive film.

The display driver 200 may include a timing controller 210 and a data driver 220.

The timing controller 210 may receive digital video data DATA and timing signals from, for example, the circuit board 300. The timing controller 210 may generate, based on the timing signals, a data control signal DCS to control the operation timing of the data driver 220, the gate control signal GCS to control the operation timing of the gate driver 610, and an emission control signal ECS to control the operation timing of an emission control driver 620, which may be disposed in the non-display area NDA. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and supply the analog data voltages to the data lines DL through the fan-out lines FL. Gate signals applied to the gate lines GL by, for example, the gate driver 610 may select the pixels PX to which the data voltage(s) may be supplied, and the selected pixels PX may receive the data voltage(s) through the data lines DL.

The power supply 500 may be disposed on the circuit board 300 to supply a power voltage to at least one of the display driver 200 and the display panel 100. The power supply 500 may generate and supply a driving voltage to the driving voltage lines VDL, generate and supply an initialization voltage to the initialization voltage lines, and generate and supply a common voltage to the common electrode, which may be common to the light emitting elements ED of the pixels PX. The common voltage may be applied to the common electrode CM through a common voltage line.

The gate driver 610 may be disposed at one (or an) external side adjacent to the display area DA or at one (or a) side of the non-display area NDA that may be different from a side of the non-display area NDA associated with the sub-region SBA. The emission control driver 620 may be disposed at the other (or another) external side adjacent to the display area DA or at the other (or another) side of the non-display area NDA that may also be different from a side of the non-display area NDA associated with the sub-region SBA. Embodiments, however, are not limited to these examples. For instance, the gate driver 610 and the emission control driver 620 may be disposed at any one or more of the various sides of the non-display area NDA.

The gate driver 610 may include multiple transistors and may be configured to generate gate signals based on the gate control signal GCS. The emission control driver 620 may include multiple transistors and may be configured to generate emission signals based on the emission control signal ECS. In some implementations, the transistors of the gate driver 610 and the transistors of the emission control driver 620 may be formed on a same layer as the transistors (or at least some of the transistors) of each of the pixels PX. The gate driver 610 may supply the gate signals to the gate lines GL, and the emission control driver 620 may supply the emission signals to the emission control lines EML.

FIG. 5 is a plan view schematically illustrating a display device according to an embodiment.

As illustrated in FIG. 5, multiple unit pixels UPX may be arranged in a display area DA of a display panel 100 of the display device 10.

Multiple pixels PX that provide light of different colors may be disposed in or form portions of a unit pixel UPX. For example, the unit pixel UPX may include three pixels PX that emit light of different colors (or different wavelengths (or different ranges of wavelengths)) from one another. In an embodiment, three pixels included in the unit pixel UPX may include a red pixel R-PX configured to emit red light, a green pixel G-PX configured to emit green light, and a blue pixel B-PX configured to emit blue light.

According to an embodiment, the blue pixel B-PX may have a larger area (e.g., cross-sectional area in a plane parallel (or substantially parallel) to a DR1-DR2 plane) than the other pixels. For example, a pixel electrode PE of the blue pixel B-PX may have, in a view in the third direction DR3, a larger area than a pixel electrode PE of the red pixel R-PX and/or a pixel electrode PE of the green pixel G-PX.

According to an embodiment, the blue pixel B-PX may have a larger emission area EA than the other pixels in a view in the third direction DR3. For example, the emission area EA of the blue pixel B-PX may have a larger area (e.g., cross-sectional area in a plane parallel (or substantially parallel) to a DR1-DR2 plane) than the emission area EA of the red pixel R-PX and/or the emission area EA of the green pixel G-PX. To this end, the blue pixel B-PX may have a larger number of emission areas EA than the other pixels. For example, the blue pixel B-PX may include two emission areas EA, and the red pixel R-PX and green pixel G-PX may each include one emission area EA.

According to an embodiment, in a view in the third direction DR3, the pixel electrode PE and the emission area EA of the pixel PX may each have a circular shape. However, embodiments of the pixel electrode PE and the emission area EA of the pixel PX are not limited to having circular shapes, and may have other or additional shapes, such as polygonal, oval, elliptical, free-form, etc.

According to an embodiment, each pixel PX may include a pixel electrode PE and at least one dummy layer DM (or dummy electrode). The dummy layer DM may improve the image quality of the display device 10 by minimizing the color difference (or color deviation) of the display device 10 depending on a viewing angle of the display device 10 by allowing the edge of the pixel electrode PE to have a stepped portion (or an inclined surface). Hereinafter, the dummy layer DM will be described in more detail.

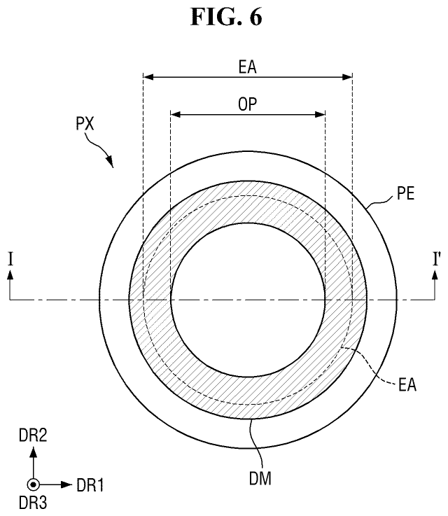

FIG. 6 is an enlarged view schematically illustrating a pixel according to an embodiment. FIG. 7 schematically illustrates is a cross-sectional view of a pixel taken along sectional line I-I′ in FIG. 6 according to an embodiment. For example, the pixel PX depicted in FIG. 6 may be an enlarged view of a representative pixel PX shown in FIG. 5.

As illustrated in FIG. 7, a display device 10 according to an embodiment may include a substrate SUB, a transistor layer TRL, a light emitting element layer EMTL, and an encapsulation layer ENC. A light blocking layer BML, at least one buffer layer, the transistor layer TRL, the light emitting element layer EMTL, and the encapsulation layer ENC may be sequentially disposed along the third direction DR3 on the substrate SUB.

The substrate SUB may be at least one of a rigid substrate and a flexible substrate, which may be configured to be elastically (or at least intentionally) bent, folded, rolled, twisted, and/or otherwise flexed. The substrate SUB may be made of an insulating material, such as at least one of glass, quartz, and polymer material, e.g., a polymer resin. The polymer material may be, for example, at least one of polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (CAT), and cellulose acetate propionate (CAP), or any combination of the polymer materials. In some embodiments, the substrate SUB may include a metal material.

A first buffer layer BF1 may be disposed on the substrate SUB. The first buffer layer BF1 may be a layer for protecting transistors of the transistor layer TRL and a light emitting layer EL of the light emitting element layer EMTL from moisture introduced through the substrate SUB, which may be vulnerable to moisture penetration. The first buffer layer BF1 may be composed of multiple inorganic layers stacked alternately with one another. For example, the first buffer layer BF1 may be a multilayer structure in which one or more inorganic layers may be alternately stacked with one another, and may include at least one of a silicon nitride layer, a silicon oxynitride layer, a silicon oxide layer, a titanium oxide layer, and an aluminum oxide layer.

The light blocking layer BML may be disposed on the first buffer layer BF1. The light blocking layer BML may be disposed on the substrate SUB and may be overlapped by an active layer ACT, which will be described later. The light blocking layer BML may be made of, for example, a metal material, such as chromium (Cr), molybdenum (Mo), and/or the like, and/or may be made of at least one of black ink and black dye. In a case that the light blocking layer BML is made of a metal material, the light blocking layer BML may receive a static power, e.g., a common voltage, a relatively low-level voltage, or the like. Accordingly, the light blocking layer BML may not float electrically, and the electrical characteristics of the transistors TR on the light blocking layer BML may be stabilized. For example, performance degradation of oxide-based transistors can be minimized or at least reduced. Oxide semiconductors may be sensitive to light, and changes in current amount may occur due to external light. The light blocking layer BML may function as a counter gate electrode of the transistor TR. The light blocking layer BML may be electrically connected to the gate electrode GE of the transistor TR described above. Accordingly, the counter gate electrode of the transistor TR and the gate electrode GE may be electrically connected to each other.

The second buffer layer BF2 may be disposed on the light blocking layer BML. The second buffer layer BF2 may include a same material as the first buffer layer BF1 described above or may include at least one different material from the first buffer layer BF1.

The active layer ACT may be disposed on the second buffer layer BF2. For example, the active layer ACT may be disposed on the second buffer layer BF2 to overlap the light blocking layer BML in, for example, the third direction DR3. The active layer ACT may be, for example, an oxide semiconductor. For example, the active layer ACT may be a semiconductor including at least one of indium-gallium-zinc-oxide (IGZO) and indium-gallium-zinc-tin oxide (IGZTO). In some implementations, the active layer ACT may be, for example, crystalline silicon, polycrystalline silicon, and/or amorphous silicon.

A gate insulating layer GI may be disposed on the active layer ACT. For example, the gate insulating layer GI may overlap a channel region CH of the active layer ACT. The gate insulating layer GI may include at least one of tetraethylorthosilicate (TEOS), silicon nitride (SiNₓ), and silicon oxide (SiO₂). For example, the gate insulating layer GI may have a double-layer structure in which a silicon nitride layer with a thickness of about 40 nm in the third direction DR3 and a tetraethylorthosilicate layer with a thickness of about 80 nm in the third direction DR3 are sequentially stacked on each other.

The gate electrode GE may be disposed on the gate insulating layer GI. The gate electrode GE may be disposed on the gate insulating layer GI to overlap the channel region CH of the active layer ACT in, for instance, the third direction DR3. The gate electrode GE may be made of at least one of aluminum (Al) and titanium (Ti), but embodiments are not limited to these materials. In some implementations, the gate electrode GE may have a double-layer or triple-layer structure in which aluminum (Al) and titanium (Ti) are stacked on each other.

A first interlayer insulating layer ITL1 may be disposed on the gate electrode GE. The first interlayer insulating layer ITL1 may be disposed on the entire (or substantially entire) surface of the substrate SUB including the gate electrode GE. The first interlayer insulating layer ITL1 may include an inorganic layer, for example, at least one of a silicon nitride layer, a silicon oxynitride layer, a silicon oxide layer, a titanium oxide layer, and an aluminum oxide layer. The first interlayer insulating layer ITL1 may include multiple inorganic layers.

A capacitor electrode CPE may be disposed on the first interlayer insulating layer ITL1. For example, the capacitor electrode CPE may be disposed on the first interlayer insulating layer ITL1 to overlap the gate electrode GE in, for instance, the third direction DR3. A capacitor may be formed in an area where the capacitor electrode CPE and the gate electrode GE overlap one another in, for instance, the third direction DR3.

A second interlayer insulating layer ITL2 may be disposed on the capacitor electrode CPE. The second interlayer insulating layer ITL2 may be disposed on the a (e.g., front) surface of the substrate SUB including the capacitor electrode CPE. The second interlayer insulating layer ITL2 may include a same material as the first interlayer insulating layer ITL1 described above or at least one different material from the first interlayer insulating layer ITL1.

A source connection electrode SCE and a drain connection electrode DCE may be disposed on the second interlayer insulating layer ITL2. The source connection electrode SCE may be electrically connected to a source electrode SE of the active layer ACT through a first contact hole CT1 penetrating each of the second interlayer insulating layer ITL2, the first interlayer insulating layer ITL1, and the gate insulating layer GI. The drain connection electrode DCE may be electrically connected to a drain electrode DE of the active layer ACT through a second contact hole CT2 penetrating each of the second interlayer insulating layer ITL2, the first interlayer insulating layer ITL1, and the gate insulating layer GI.

A first passivation layer VA1 may be disposed on the source connection electrode SCE and the drain connection electrode DCE. For example, the first passivation layer VA1 may be disposed on the front surface of the substrate SUB including the source connection electrode SCE and the drain connection electrode DCE. The first passivation layer VA1 may be made of a same material as the first interlayer insulating layer ITL1 or at least one different material from the first interlayer insulating layer ITL1.

A pixel connection electrode PCE and a dummy layer DM may be disposed on the first passivation layer VA1. The pixel connection electrode PCE may be electrically connected to the source connection electrode SCE through a third contact hole CT3 penetrating the first passivation layer VA1.

A second passivation layer VA2 may be disposed on the pixel connection electrode PCE and the dummy layer DM. For example, the second passivation layer VA2 may be disposed on the front surface of the substrate SUB including the pixel connection electrode PCE and the dummy layer DM. The second passivation layer VA2 may be made of a same material as the first interlayer insulating layer ITL1 or at least one different material than the first interlayer insulating layer ITL1.

The light emitting element layer EMTL including a pixel electrode PE, a light emitting element ED, and a pixel defining layer PDL may be disposed on the second passivation layer VA2. The pixel electrode PE may be electrically connected to the pixel connection electrode PCE through a fourth contact hole CT4 penetrating the second passivation layer VA2. The pixel electrode PE may be electrically connected to the source electrode SE of the active layer ACT through the pixel connection electrode PCE and the source connection electrode SCE.

The light emitting element ED may include the pixel electrode PE, the light emitting layer EL, and the common electrode CM. An emission area EA may be an area where the pixel electrode PE, the light emitting layer EL, and the common electrode CM are sequentially stacked to allow holes from the pixel electrode PE and electrons from the common electrode CM to be combined with each other in the light emitting layer EL to emit light. In some cases, the pixel electrode PE may be an anode of the light emitting element ED, and the common electrode CM may be a cathode of the light emitting element ED. In some implementations, the pixel electrode PE may be the cathode of the light emitting element ED, and the common electrode CM may be the anode of the light emitting element ED.

In a top emission structure in which light is emitted in a direction from the light emitting layer EL toward the common electrode CM, the pixel electrode PE may be formed as a single layer of at least one of molybdenum (Mo), titanium (Ti), copper (Cu), and aluminum (Al), or, in order to increase reflectivity, may be formed as at least one of a stacked structure (Ti/Al/Ti) of aluminum and titanium, a stacked structure (ITO/AI/ITO) of aluminum and indium tin oxide, an APC alloy, and a stacked structure (ITO/APC/ITO) of an APC alloy and indium tin oxide. The APC alloy may be an alloy including silver (Ag), palladium (Pd), and copper (Cu).

The pixel defining layer PDL may define (or at least partially bound) the emission areas EA of the pixels PX. To this end, the pixel defining layer PDL may be disposed on a planarization layer and may expose corresponding portions of the pixel electrodes PE of the pixels PX. The pixel defining layer PDL may cover edges of the pixel electrodes PE. The pixel defining layer PDL may be made of an organic layer, and thereby, may include an organic material, such as at least one of acryl resin, epoxy resin, phenolic resin, polyamide resin, and polyimide resin.

A spacer SPC may be disposed on, extend from, and/or form a portion of the pixel defining layer PDL. The spacer SPC may support a mask during a process of manufacturing the light emitting layer EL. The spacer SPC may be made of an organic layer, and thereby, may include an organic material, such as at least one of acryl resin, epoxy resin, phenolic resin, polyamide resin, and polyimide resin.

The light emitting layer EL may be formed on the pixel electrode PE. The light emitting layer EL may include an organic material configured to emit light of a determined color. For example, the light emitting layer EL may include a hole transporting layer, an organic material layer, and an electron transporting layer. The organic material layer may include a host and a dopant. The organic material layer may include a material that emits light of a determined color and may be formed using at least one of a phosphorescent material and a fluorescent material.

For example, the organic material layer of the light emitting layer EL configured to emit light of the first color (e.g., a blue color) may be a phosphorescent material that includes a host material including at least one of CBP and mCP and a dopant material including at least one of (4,6-F2ppy)2Irpic and L2BD111. However, embodiments are not limited to the aforementioned materials.

The organic material layer of the light emitting layer EL configured to emit light of the second color (e.g., a green color) may be a phosphorescent material that includes a host material including at least one of CBP and mCP and a dopant material including, for example, Ir(ppy)3(fac tris(2-phenylpyridine)iridium). In some implementations, the organic material layer of the light emitting layer EL configured to emit light of the second color may be a fluorescent material including tris(8-hydroxyquinolino)aluminum (Alq3). However, embodiments are not limited to the above-noted materials.

The organic material layer of the light emitting layer EL configured to emit light of the third color (e.g., a red color) may be a phosphorescent material that includes a host material including at least one of carbazole biphenyl (CBP) and 1,3-bis(carbazol-9-yl)(mCP) and a dopant including at least one of bis(1-phenylisoquinoline) acetylacetonate iridium (PIQIr(acac)), bis(1-phenylquinoline) acetylacetonate iridium (PQIr(acac)), tris(1-phenylquinoline)iridium (PQIr) and octaethylporphyrin platinum (PtOEP). In some implementations, the organic material layer of the light emitting layer EL configured to emit light of the third color may be a fluorescent material including at least one of PBD:Eu(DBM)3(Phen) and perylene. However, embodiments are not limited to the above-noted materials.

As shown in FIG. 7, the dummy layer DM may be disposed on the first passivation layer VA1. For example, the dummy layer DM may be disposed directly on the first passivation layer VA1 to be in direct contact with the first passivation layer VA1. According to an embodiment, the dummy layer DM may be disposed between the first passivation layer VA1 and the pixel electrode PE in, for instance, the third direction DR3. A portion of the second passivation layer VA2 may be disposed between the dummy layer DM and the pixel electrode PE in, for example, the third direction DR3.

The dummy layer DM may overlap the pixel electrode PE in the third direction DR3, as shown in FIGS. 6 and 7. For example, at least a portion of the dummy layer DM may overlap the pixel electrode PE in the third direction DR3 in the emission area EA.

The dummy layer DM may have a closed curve shape with an opening OP in a view in the third direction. For instance, an outer boundary of the dummy layer BM may, in a view in the third direction, circumscribe an inner boundary of the dummy layer DM defining or bounding the opening OP. For example, the dummy layer DM may have a ring shape with the opening OP at a center of the dummy layer DM. The opening OP of the dummy layer DM may overlap the emission area EA in, for instance, the third direction DR3.

As shown in FIG. 6, in a view in the third direction DR3, the opening OP of the dummy layer DM may be smaller than the emission area EA. For instance, an outer boundary of the emission area EA may, in a view in the third direction, circumscribe the opening OP of the dummy layer DM. The opening OP of the dummy layer DM may be disposed in the emission area EA. For instance, the opening OP of the dummy layer DM may be surrounded by the emission area EA in a view in the third direction DR3.

As shown in FIGS. 6 and 7, a portion of the dummy layer DM may overlap the emission area EA in, for instance, the third direction DR3, and another portion of the dummy layer DM may overlap the pixel defining layer PDL in, for instance, the third direction DR3. For example, the portion of the dummy layer DM that is closer to the opening OP of the dummy layer DM may overlap the emission area EA in the third direction DR3, and the portion of the dummy layer DM that is further from the opening OP of the dummy layer DM may overlap the pixel defining layer PDL in the third direction DR3.

As shown in FIG. 7, one side of the dummy layer DM may be disposed within the emission area EA. For example, an inner surface (e.g., inner peripheral surface or inner edge) of the dummy layer DM that defines the inner wall of the opening OP of the dummy layer DM may be disposed within the emission area EA. At this time, as shown in the example in FIG. 7, the inner surface of the dummy layer DM may be disposed close to the inner surface of the pixel defining layer PDL (e.g., the inner surface (e.g., inner peripheral surface or inner edge) of the pixel defining layer PDL defining the inner wall of the emission area EA).

As shown in FIG. 7, as at least a portion of the dummy layer DM may overlap the pixel electrode PE in the emission area EA, a stepped portion ST may be formed at a portion of the pixel electrode PE disposed on the top portion of the dummy layer DM. For example, as shown in FIG. 7, as the pixel electrode PE and the dummy layer DM overlap at an edge of the emission area EA in the third direction DR3, the pixel electrode PE may have the stepped portion ST at the edge of the emission area EA. For example, the pixel electrode PE may have the stepped portion ST in an area overlapping with the inner surface of the dummy layer DM in, for instance, the third direction DR3. The second passivation layer VA2 on the dummy layer DM may have a stepped portion at a portion corresponding to an edge of the dummy layer DM, and the edge of the pixel electrode PE overlapping the stepped portion of the second passivation layer VA2 may have the stepped portion ST. Accordingly, the pixel electrode PE may have the stepped portion ST along the edge of the emission area EA, e.g., the stepped portion ST may circumferentially extend along the edge of the emission area EA in a view in the third direction DR3.

According to an embodiment, the dummy layer DM may receive a static power. For example, a direct current voltage may be applied to the dummy layer DM. The dummy layer DM may be electrically connected to a static power supply line. The static power supply line may be, for example, any one of the driving voltage lines VDL, an initialization voltage line, and the common voltage line described above.

The dummy layer DM may be made of a material including metal. For example, the dummy layer DM may be formed as a single layer of at least one of molybdenum (Mo), titanium (Ti), copper (Cu), and aluminum (Al), or, in order to increase reflectivity, may be formed as at least one of a stacked structure (Ti/Al/Ti) of aluminum and titanium, a stacked structure (ITO/Al/ITO) of aluminum and indium tin oxide, an APC alloy, and a stacked structure (ITO/APC/ITO) of an APC alloy and indium tin oxide. The APC alloy may be an alloy including silver (Ag), palladium (Pd), and copper (Cu).

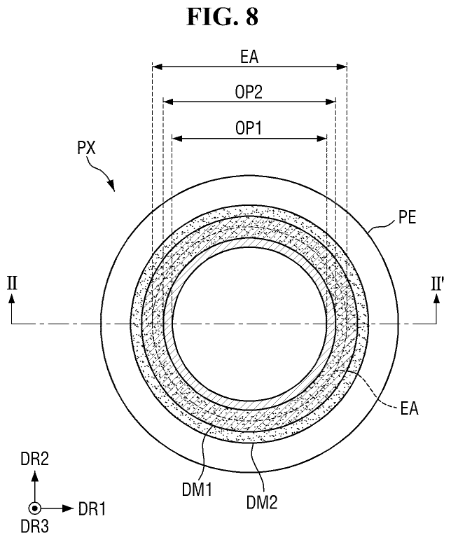

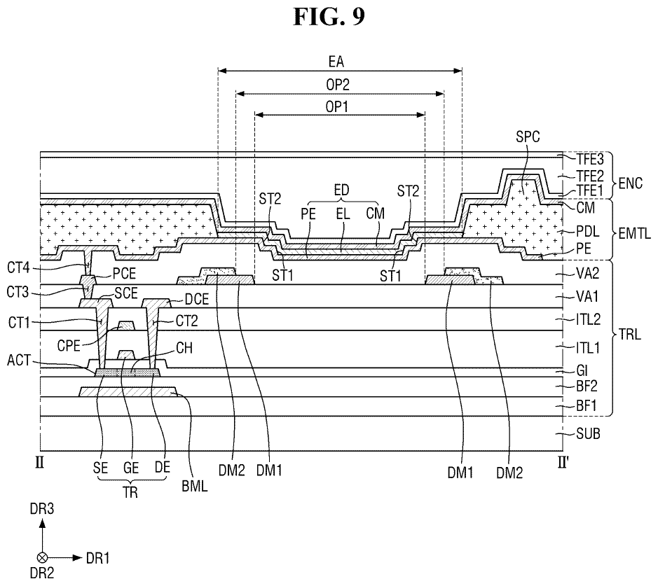

FIG. 8 is an enlarged view schematically illustrating a pixel PX according to an embodiment. FIG. 9 schematically illustrates a cross-sectional view of a pixel taken along sectional line II-II′ in FIG. 7 according to an embodiment.

The pixels PX shown in FIGS. 8 and 9 are different from the pixels PX described in association with FIGS. 6 and 7 in that the pixels PX in FIGS. 8 and 9 also include a second dummy layer DM2 in addition to the first dummy layer DM1. As such, differences will be mainly described below.

As shown in FIGS. 8 and 9, the pixel PX may include multiple dummy layers (e.g., first and second dummy layers DM1 and DM2) arranged on (or in) different layers from one another. For example, the pixel PX may include a first dummy layer DM1 and a second dummy layer DM2 disposed on different layers from one another with respect to the third direction DR3. The second dummy layer DM2 may be disposed on the first dummy layer DM1.

As shown in FIGS. 8 and 9, the pixel PX may include the first dummy layer DM1 and the second dummy layer DM2. The first dummy layer DM1 and the first opening OP1 of the first dummy layer DM1 may be configured the same as the dummy layer DM and the opening OP of the dummy layer DM described in association with FIGS. 6 and 7, respectively.

As shown in FIG. 9, the second dummy layer DM2 may be disposed on the first dummy layer DM1. For example, the second dummy layer DM2 may be disposed directly on the first dummy layer DM1 to be in direct contact with the first dummy layer DM1. According to an embodiment, the second dummy layer DM2 may be disposed between the first dummy layer DM1 and the pixel electrode PE in, for instance, the third direction DR3. A portion of the second passivation layer VA2 may be disposed between the second dummy layer DM2 and the pixel electrode PE in, for instance, the third direction DR3.

A portion of the second dummy layer DM2 may be disposed on, for example, the second passivation layer VA2. A portion of the second dummy layer DM2 may be disposed directly on the first passivation layer VA1 to be in direct contact with the first passivation layer VA1. According to an embodiment, a portion of the second dummy layer DM2 may be disposed between the first passivation layer VA1 and the pixel electrode PE in, for example, the third direction DR3. A portion of the second passivation layer VA2 may be disposed between a portion of the second dummy layer DM2 and the pixel electrode PE in, for instance, the third direction DR3.

As shown in FIGS. 8 and 9, the second dummy layer DM2 may overlap the pixel electrode PE and the first dummy layer DM1 in, for example, the third direction DR3. For example, at least a portion of the second dummy layer DM2 may overlap the pixel electrode PE and the first dummy layer DM1 in the third direction DR3 in the emission area EA.

The second dummy layer DM2 may have a closed curve shape with a second opening OP2 in a view in the third direction DR3. For instance, in a view in the third direction DR3, an outer boundary of the second dummy layer DM2 may circumscribe an inner boundary of the second dummy layer DM2 defining or bounding the second opening OP2. For example, the second dummy layer DM2 may have a ring shape with a second opening OP2 at a center of the second dummy layer DM2. The second opening OP2 of the second dummy layer DM2 may overlap the emission area EA and the first opening OP1 of the first dummy layer DM1 in, for example, the third direction DR3.

As shown in FIG. 8, in a view in the third direction DR3, the second opening OP2 of the second dummy layer DM2 may be larger than the first opening OP1 of the first dummy layer DM1 and smaller than the emission area EA. For instance, a cross-sectional area of the second opening OP2 of the second dummy layer DM2 in a first plane perpendicular to the third direction DR3 may be larger than a cross-sectional area of the first opening OP1 of the first dummy layer DM1 in a second plane perpendicular to the third direction DR3. Further, the cross-sectional area of the second opening OP2 of the second dummy layer DM2 in the first plane may be smaller than a cross-sectional area of the emission area EA in a third plane perpendicular to the third direction DR3. The first plane, the second plane, and the third plane may be parallel (or substantially parallel) to one another, and in some embodiments, may be parallel (or substantially parallel) with the DR2-DR1 plane. The second opening OP2 of the second dummy layer DM2 may be disposed in the emission area EA. For instance, the second opening OP2 of the second dummy layer DM2 may be surrounded by the emission area EA in a view in the third direction DR3. For example, an outer boundary of the emission area EA may, in a view in the third direction DR3, circumscribe the second opening OP2. The first opening OP1 of the first dummy layer DM1 may be surrounded by the second opening OP2 of the second dummy layer DM2 and the emission area EA in a view in the third direction DR3. For instance, both an outer boundary of the second opening OP2 of the second dummy layer DM2 and an outer boundary of the emission area EA may circumscribe an outer boundary of the first opening OP1 of the first dummy layer DM1.

As shown in FIGS. 8 and 9, a portion of the second dummy layer DM2 may overlap the emission area EA in, for instance, the third direction DR3, and another portion of the second dummy layer DM2 may overlap the pixel defining layer PDL in, for instance, the third direction DR3. For example, a portion of the second dummy layer DM2 that is closer to the second opening OP2 of the second dummy layer DM2 may overlap the emission area EA in the third direction DR3, and another portion of the second dummy layer DM2 that is further from the second opening OP2 of the second dummy layer DM2 may overlap the pixel defining layer PDL in the third direction DR3.

As shown in FIG. 9, one (or a) side of the second dummy layer DM2 may be disposed in the emission area EA. For example, the inner surface (e.g., inner peripheral surface or inner edge) of the second dummy layer DM2 that defines (or bounds) the inner wall of the second opening OP2 of the second dummy layer DM2 may be disposed in the emission area EA in a view in the third direction DR3. As shown in the example in FIG. 9, the inner surface of the second dummy layer DM2 may be disposed closer to the inner surface of the pixel defining layer PDL (e.g., the inner surface of the pixel defining layer PDL defining or bounding the inner wall of the emission area EA) than the inner surface of the first dummy layer DM1.

According to an embodiment, in a view in the third direction DR3, the inner surface of the second dummy layer DM2 may be disposed between the inner surface of the pixel defining layer PDL and the inner surface of the first dummy layer DM1.

As shown in FIG. 9, at least a portion of the first dummy layer DM1 and at least a portion of the second dummy layer DM2 may overlap the pixel electrode PE in the emission area EA in, for instance, the third direction DR3, such that stepped portions ST1 and ST2 are formed at a portion of the pixel electrode PE disposed on the top portion of the first dummy layer DM1 and the second dummy layer DM2. For example, as shown in FIG. 9, as the pixel electrode PE and the dummy layers DM1 and DM2 overlap in the third direction DR3 at an edge of the emission area EA, the pixel electrode PE may have multiple stepped portions ST1 and ST2 of different heights at the edge of the emission area EA. For example, the pixel electrode PE may have a first stepped portion ST1 in the area overlapping with the inner surface of the first dummy layer DM1 in, for example, the third direction DR3, and the pixel electrode PE may have a second stepped portion ST2 in the area overlapping with the inner surface the second dummy layer DM2 in, for instance, the third direction DR3. The second passivation layer VA2 on the first dummy layer DM1 may have a stepped portion at a portion corresponding to the edge of the first dummy layer DM1, and the edge of the pixel electrode PE that overlaps with the stepped portion of the second passivation layer VA2 in, for example, the third direction DR3 may have the first stepped ST1. The second passivation layer VA2 on the second dummy layer DM2 may have a stepped portion at a portion corresponding to the edge of the second dummy layer DM2, and the edge of the pixel electrode PE overlapping with the stepped portion of the second passivation layer VA2 in, for example, the third direction DR3 may have the second stepped portion ST2. Accordingly, the pixel electrode PE may have the first and second stepped portions ST1 and ST2 along the edge of the emission area EA, e.g., the first and second stepped portion ST1 and ST2 may circumferentially extend along the edge of the emission area EA.

According to an embodiment, since the second dummy layer DM2 may be disposed higher in the third direction DR3 than the first dummy layer DM1 (e.g., the second dummy layer DM2 may be disposed further from the substrate SUB in the third direction DR3 than the first dummy layer DM1), the second stepped portion ST2 generated by or in association with the second dummy layer DM2 may be disposed higher in the third direction DR3 than the first stepped portion ST1 generated by or in association with the first dummy layer DM1.

According to an embodiment, at least one of the first dummy layer DM1 and the second dummy layer DM2 may be supplied with the static power described above. To this end, at least one of the first dummy layer DM1 and the second dummy layer DM2 may be electrically connected to a static power supply line. The static power supply line may be, for example, any one of the driving voltage lines VDL, the initialization voltage lines, and the common voltage line described above.

The first dummy layer DM1 and the second dummy layer DM2 may include a same material as the dummy layer DM described above. For example, the first dummy layer DM1 and the second dummy layer DM2 may each be made of a material including metal, but embodiments are not limited to the above-noted materials.

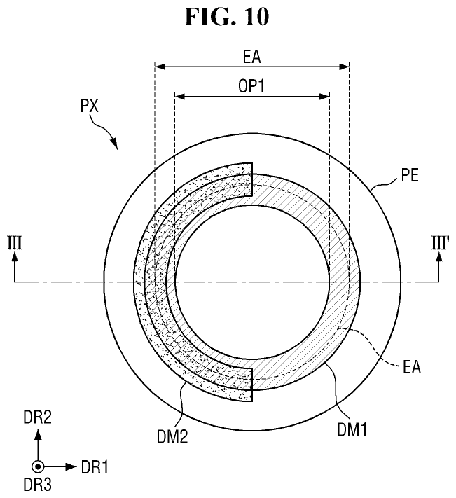

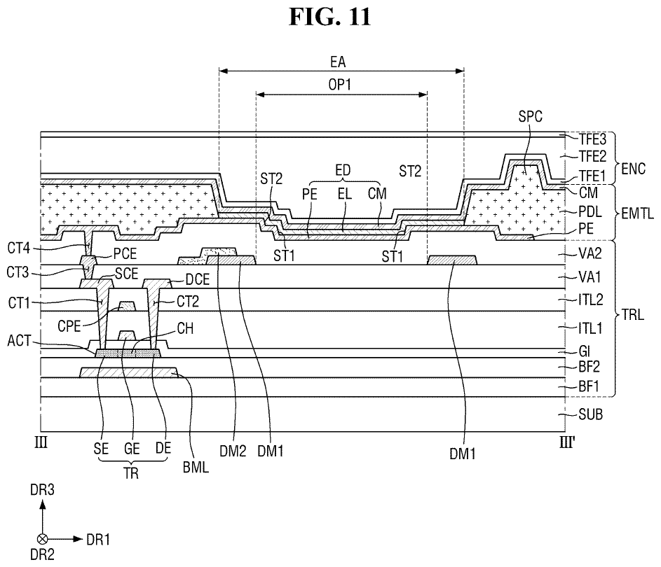

FIG. 10 is an enlarged view schematically illustrating a pixel according to an embodiment. FIG. 11 schematically illustrates a cross-sectional view of a pixel taken along sectional line III-III′ in FIG. 10 according to an embodiment.

The pixels PX shown in FIGS. 10 and 11 are different from the pixels PX described in association with FIGS. 8 and 9 in the shape of the second dummy layer DM2. As such, the differences will be mainly described below.

As shown in the example in FIG. 10, an edge of the emission area EA may be divided into at least two areas (hereinafter referred to as “step areas”), and the first and second dummy layers DM1 and DM2 of different numbers may be disposed in (or on) the different step areas. For example, as shown in FIGS. 10 and 11, a portion (e.g., a first step ST1 area) of the edge of the emission area EA may overlap the first dummy layer DM1 and the second dummy layer DM2 in, for instance, the third direction DR3, and a remaining (or another) portion of the edge of the emission area EA (e.g., a second step ST2 area) may overlap any one dummy layer (e.g., the first dummy layer DM1) in, for example, the third direction.

According to an embodiment, as shown in FIG. 10, in the emission area EA, an overlapping area between the first dummy layer DM1 and the pixel electrode PE in, for instance, the third direction DR3 (hereinafter, a “first overlapping area”) may be larger than an overlapping area between the second dummy layer DM2 and the pixel electrode PE in, for example, the third direction DR3 (hereinafter, a “second overlapping area”) in a view in the third direction DR3. The first overlapping area may be larger than the second overlapping area.

According to an embodiment, as shown in FIG. 10, the second dummy layer DM2 may have a different shape from the first dummy layer DM1. For example, the second dummy layer DM2 may have a C-shape. Accordingly, only a portion of the outer surface (or outer edge) of the first dummy layer DM1 may be overlapped by the second dummy layer DM2 in, for instance, the third direction DR3. According to an embodiment, half of the outer surface (e.g., outer peripheral surface or outer edge) of the first dummy layer DM1 may be covered by the second dummy layer DM2.

As shown in FIG. 11, since the edges of the emission area EA may be overlapped by one or more dummy layers DM of different numbers, the pixel electrode PE may have stepped portions of different numbers in an edge (e.g., the first step ST1 area in which the first dummy layer DM1 and the second dummy layer DM2 are disposed) and another edge (e.g., the second step ST2 area in which the first dummy layer DM1 is disposed) of the emission area EA. For example, as shown in FIG. 11, the pixel electrode PE may have two steps (e.g., the first stepped portion ST1 and the second stepped portion ST2) of different heights in the first step ST1 area, and one step (e.g., a step of the same height as the first step ST1) in the second step ST2 area.

According to an embodiment, at least two pixels PX may have different numbers of dummy layers. For example, a first pixel PX among the pixels PX described in association with FIG. 5 may include one dummy layer DM as shown in FIG. 6, and a second pixel PX among the pixels PX described in association with FIG. 5 may include multiple dummy layers (e.g., the first dummy layer DM1 and the second dummy layer DM2) as shown in FIG. 8 or FIG. 10.

According to some embodiments, the number of steps on an edge (or a portion of an edge) of the pixel electrode PE may be different from the number of steps on another edge (or another portion of the edge) of the pixel electrode PE. Accordingly, since the steps may be asymmetrically arranged about a central axis of a pixel electrode PE extending in the third direction DR3, the color difference depending on a viewing angle can be further reduced, thereby further improving the image quality of the display device 10.

The pixels PX described in association with FIG. 5 may be divided in to a first pixel group PG1 and a second pixel group PG2 based on an extending direction (e.g., the second direction DR2) of the data lines DL. For example, the first pixel group PG1 may include unit pixels UPX in odd-numbered columns, and the second pixel group PG2 may include unit pixels UPX in even-numbered columns.

According to an embodiment, the pixel PX of the first pixel group PG1 and the pixel PX of the second pixel group PG2 may have different numbers of dummy layers DM. For example, each pixel PX of the unit pixels UPX included in the first pixel group PG1 may include one dummy layer DM, such as shown in FIG. 6, and each pixel PX of the unit pixels UPX included in the second pixel group PG2 may include multiple dummy layers (e.g., the first and second dummy layers DM1 and DM2), such as shown in FIG. 8 or 10.

According to various embodiments, in a case that the number of dummy layers DM is different for each pixel group, the stepped portions of the pixel electrodes PE may be arranged asymmetrically in a view in the third direction DR3. Accordingly, the color difference depending on a viewing angle can be further reduced and the image quality of the display device 10 can be further improved.

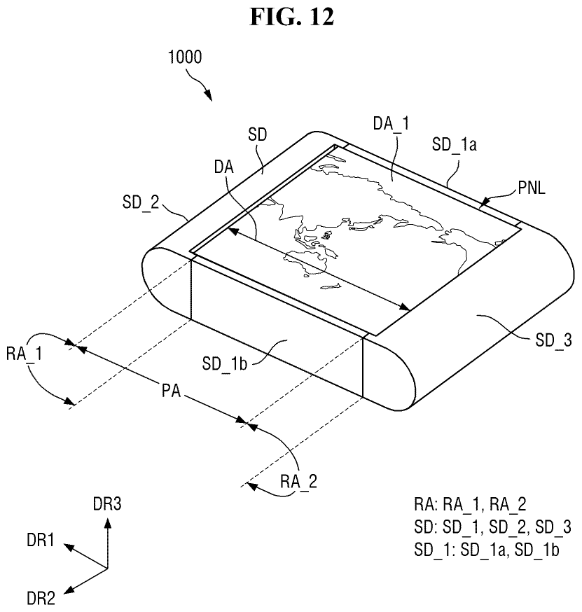

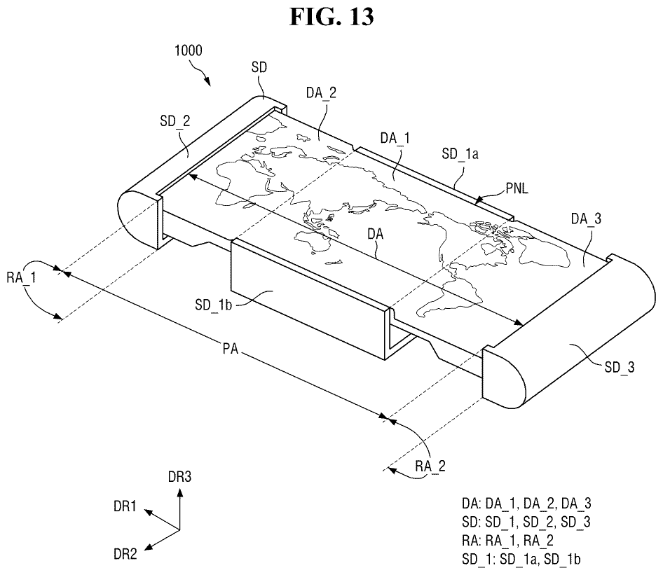

FIG. 12 is a perspective view schematically illustrating a display device according to an embodiment. FIG. 13 is a perspective view schematically illustrating a display device in an expanded state according to an embodiment.

Referring to FIGS. 12 and 13, the display device 1000 according to an embodiment may include a display panel PNL and a panel storage container SD.

The display panel PNL may be a panel for displaying a screen, and any type of display panel, such as an organic light emitting display panel including an organic light emitting layer, a micro light emitting diode display panel using a micro light emitting diode (LED), a nano light emitting diode display panel using a nano light emitting diode (LED), a quantum dot light emitting display panel using a quantum dot light emitting diode including a quantum dot light emitting layer, or an inorganic light emitting display panel using an inorganic light emitting element including an inorganic semiconductor may be applied as the display panel PNL.

The display panel PNL may be a flexible panel. The display panel PNL may have flexibility to be partially rolled, bent, curved, twisted, or otherwise flexed in the panel storage container SD, as will be described later. The display panel PNL may be slid in the first direction DR1.

The display panel PNL may include an active region and a non-active region. The active region of the display panel PNL may be an area where the plurality of pixels are disposed. The non-active region of the display panel PNL may be an area in which no pixel is disposed. Metal lines, such as data lines, scan lines, touch lines, and/or power voltage lines, may be disposed in the non-active region. The non-active region may be disposed to surround the active region and/or outside the active region.

The display area DA of the display panel PNL may be an area in which a screen is displayed. The display area DA may be divided into a first display area DA_1, a second display area DA_2, and a third display area DA_3 according to whether the display panel PNL slides or the sliding degree of the display panel PNL. The presence and size of the second display area DA_2 and the third display area DA_3 may vary according to whether the display panel PNL slides or the sliding degree of the display panel PNL. In a non-sliding state, the display panel PNL has the first display area DA_1 having a first size. In a sliding state, the display area DA further includes the second display area DA_2 and the third display area DA_3 expanded in addition to the first display area DA_1.

The sizes of the second display area DA_2 and the third display area DA_3 may vary according to the degree of sliding. For example, in a state in which the display device 1000 is slid to a maximum amount, the second display area DA_2 may have a second size, the third display area DA_3 may have a third size, and the display area DA may have a fourth size that is the sum of the first area, the second area, and the third area. The fourth area may be a maximum area that the display area DA may have.

As shown in FIGS. 12 and 13, the panel storage container SD may serve to accommodate at least a part of the display panel PNL and assist the sliding operation of the display device 1000. The panel storage container SD may include a first storage container SD_1 located at the center (or a central area) of the display device 1000, a second storage container SD_2 that may be disposed at one (or a) side of the first storage container SD_1 in the first direction DR1 and may have the first display device bending area RA_1, and a third storage container SD_3 that may be disposed at the other (or another) side of the first storage container SD_1 in the first direction DR1 and may have a second display device bending area RA_2.

The first storage container SD_1 may connect the second storage container SD_2 and the third storage container SD_3 to each other. For instance, the first storage container SD_1 may include a first_first storage container SD_1a, which connects the other side of the second storage container SD_2 in the second direction DR2 and the other side of the third storage container SD_3 in the second direction DR2, and a first_second storage container SD_1b, which connects one side of the second storage container SD_2 in the second direction DR2 and one side of the third storage container SD_3 in the second direction DR2.

In some embodiments, rails may be formed in or on the second storage container SD_2 and the third storage container SD_3 to guide the sliding operation of the display panel PNL, but embodiments are not limited to these examples.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A display device comprising:
a substrate;
a pixel electrode disposed on a surface of the substrate;
a pixel defining layer disposed on the pixel electrode, the pixel defining layer at least partially bounding an emission area overlapping the pixel electrode in a direction perpendicular to the surface;
a light emitting layer disposed on the pixel electrode;
a common electrode disposed on the light emitting layer; and
a first dummy layer overlapping the pixel electrode in the emission area in the direction.

2. The display device of claim 1, wherein the pixel electrode comprises a first stepped portion in an area overlapping the first dummy layer in the direction.

3. The display device of claim 2, wherein the pixel electrode overlaps the first dummy layer in the direction at an edge of the emission area.

4. The display device of claim 1, wherein the first dummy layer is disposed between the substrate and the pixel electrode in the direction.

5. The display device of claim 1, wherein the first dummy layer comprises a first opening overlapping the emission area in the direction.

6. The display device of claim 5, wherein, in a view in the direction, an outer boundary of the emission area circumscribes the first opening.

7. The display device of claim 5, wherein
a first portion of the first dummy layer overlaps the emission area in the direction,
a second portion of the first dummy layer overlaps the pixel defining layer in the direction, and
the first portion is closer to the first opening than the second portion.

8. The display device of claim 5, wherein, in a view in the direction, an outer boundary of the first dummy layer circumscribes an inner boundary of the first dummy layer defining the first opening.

9. The display device of claim 8, further comprising:
a static power supply line electrically connected to the first dummy layer.

10. The display device of claim 1, wherein the first dummy layer comprises a metal material.

11. The display device of claim 1, further comprising:
an insulating layer between the first dummy layer and the pixel electrode in the direction.

12. The display device of claim 11, wherein the insulating layer comprises a first stepped portion in an area in which the pixel electrode and the dummy layer overlap each other in the direction.

13. The display device of claim 1, further comprising:
a second dummy layer disposed on the first dummy layer.

14. The display device of claim 13, wherein the pixel electrode comprises:
a first stepped portion in an area overlapping the first dummy layer in the direction; and
a second stepped portion in an area overlapping the second dummy layer in the direction.

15. The display device of claim 14, wherein the pixel electrode overlaps both the first dummy layer and the second dummy layer in the direction at an edge of the emission area.

16. The display device of claim 13, wherein
the first dummy layer is disposed between the substrate and the pixel electrode in the direction, and
the second dummy layer is disposed between the first dummy layer and the pixel electrode in the direction.

17. The display device of claim 13, wherein
the first dummy layer comprises a first opening overlapping the emission area in the direction, and
the second dummy layer comprises a second opening overlapping the emission area in the direction.

18. The display device of claim 17, wherein, in a view in the direction
an outer boundary of the second opening circumscribes an outer boundary of the first opening, and
an outer boundary of the emission area circumscribes an outer boundary of the second opening.

19. The display device of claim 17, wherein
a cross-sectional area of the second opening of the second dummy layer in a first plane perpendicular to the direction is larger than a cross-sectional area of the first opening of the first dummy layer in a second plane perpendicular to the direction,
the cross-sectional area of the second opening of the second dummy layer in the first plane is smaller than a cross-sectional area of the emission area in a third plane perpendicular to the direction, and
the first plane, the second plane, and the third plane are parallel with one another.

20. The display device of claim 17, wherein, in a view in the direction, an inner surface of the second dummy layer is disposed between an inner surface of the pixel defining layer and an inner surface of the first dummy layer.

21. The display device of claim 13, wherein, in the emission area, an amount of overlapping area between the first dummy layer and the pixel electrode in the direction is greater than an amount of overlapping area between the second dummy layer and the pixel electrode in the direction.

22. A display device comprising:
a substrate;
a first pixel electrode disposed on a surface of the substrate;
a second pixel electrode disposed on the surface;
a first emission area overlapping the first pixel electrode in a direction perpendicular to the surface;
a second emission area overlapping the second pixel electrode in the direction;
a first light emitting layer disposed on the first pixel electrode;
a second light emitting layer disposed the second pixel electrode;
a common electrode disposed on both the first light emitting layer and the second light emitting layer;
a first dummy layer overlapping, in the first emission area, the first pixel electrode in the direction;
a second dummy layer overlapping, in the second emission area, the second pixel electrode in the direction; and
a third dummy layer disposed on the second dummy layer and overlapping, in the second emission area, the second pixel electrode in the direction.

23. The display device of claim 22, wherein
the first pixel electrode is part of a first pixel group, and
the second pixel electrode is part of a second pixel group different from the first pixel group.
